(19) United States
(12) Patent Application Publication
(10) Pub. No.: US 2026/0271243 A1
(43) Pub. Date: Sep. 10, 2026

(54) LIQUID COOLING HEAT DISSIPATION ASSEMBLY AND SERVER DEVICE INCLUDING THE SAME

(71) Applicants: INVENTEC (PUDONG) TECHNOLOGY CORPORATION, Shanghai (CN); INVENTEC CORPORATION, Taipei City (TW)

(72) Inventors: Kunlong ZHANG, Shanghai (CN); Yi-dong JI, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 19/201,299

(22) Filed: May 7, 2025

(30) Foreign Application Priority Data
Mar. 7, 2025 (CN) 202510273708.2

(51) Int. Cl. H05K 7/20

(52) U.S. Cl. CPC H05K 7/20809

(57) ABSTRACT

A liquid cooling heat dissipation assembly is configured for cooling a central processing unit and at least one voltage regulator. The liquid cooling heat dissipation assembly includes a cold plate, at least one thermally conductive metal component and at least one heat pipe. The cold plate is configured to be in thermal contact with the central processing unit and for a coolant to flow through. The thermally conductive metal component is configured to be in thermal contact with the voltage regulator. Two ends of the heat pipe are respectively thermally coupled to the cold plate and the thermally conductive metal component.

### CROSS-REFERENCE TO RELATED APPLICATIONS

This non-provisional application claims priority under 35 U.S.C. § 119(a) on Patent Application No(s). 202510273708.2 filed in C hina, on Mar. 7, 2025, the entire contents of which are hereby incorporated by reference.

### BACKGROUND OF THE INVENTION

### Technical Field of the Invention

The invention relates to a liquid cooling heat dissipation assembly and a server device including the same, especially to an integrated liquid cooling heat dissipation assembly and a server device including the same.

### Description of the Related Art

With the continuous advancement of artificial intelligence (AI), AI products have emerged in rapid succession, leading to an increasing market demand for computing power. To enhance computing speed, server performance must be correspondingly improved. However, the computational capability of high-performance servers is typically accompanied by higher power consumption, necessitating more efficient cooling solutions for high-performance chips.

In recent years, countries worldwide have been actively promoting energy conservation and carbon reduction, bringing the energy consumption of data centers into sharp focus. Conventional air-cooled servers primarily rely on high-speed fans to cool internal heat-generating components. However, this cooling method is characterized by high energy consumption, excessive noise, and low cooling efficiency. In conventional servers, the central processing unit (CPU) is typically the primary high-power heat-generating component. Moreover, in high-power CPU environments, power modules responsible for stable power delivery, such as voltage regulators (VRs), also generate significant heat.

Therefore, effectively addressing the cooling challenges of CPUs and their power modules has become a key research focus in server cooling technology.

### SUMMARY OF THE INVENTION

The invention provides a liquid cooling heat dissipation assembly and a server device including the same capable of addressing the issues of high energy consumption, excessive noise and low cooling efficiency in conventional air-cooled servers.

One embodiment of the invention provides a liquid cooling heat dissipation assembly configured for cooling a central processing unit and at least one voltage regulator. The liquid cooling heat dissipation assembly includes a cold plate, at least one thermally conductive metal component and at least one heat pipe. The cold plate is configured to be in thermal contact with the central processing unit and for coolant to flow though. The thermally conductive metal component is configured to be in thermal contact with the voltage regulator. Two ends of the heat pipe are respectively thermally coupled to the cold plate and the thermally conductive metal component.

One embodiment of the invention provides a server device including a motherboard, a central processing unit, at least one voltage regulator and a liquid cooling heat dissipation assembly. The central processing unit is disposed on the motherboard. The voltage regulator is disposed on the motherboard. The liquid cooling heat dissipation assembly includes a cold plate, at least one thermally conductive metal component and at least one heat pipe. The cold plate is in thermal contact with the central processing unit and configured for coolant to flow through. The thermally conductive metal component is in thermal contact with the voltage regulator. Two ends of the heat pipe are respectively thermally coupled to the cold plate and the thermally conductive metal component.

According to the liquid cooling heat dissipation assembly and the server device as discussed in the above embodiments, through the design of the integrated liquid cooling heat dissipation assembly, effective cooling can be achieved for both the central processing unit and the voltage regulator. The cold plate is in thermal contact with the central processing unit, while the heat generated by the voltage regulator is transferred to the cold plate via the thermally conductive metal component and the heat pipe. Finally, the heat from both the central processing unit and the voltage regulator is carried away together by the coolant flowing through the cold plate, thereby achieving efficient cooling of both the central processing unit and voltage regulator via the liquid cooling heat dissipation assembly.

### BRIEF DESCRIPTION OF THE DRAWINGS

The invention will become more fully understood from the detailed description given hereinbelow and the accompanying drawings which are given by way of illustration only and thus are not limitative of the invention and wherein:

FIG. 1 is a partial perspective view of a server device according to one embodiment of the invention; and

FIG. 2 is a side view of the server device as shown in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

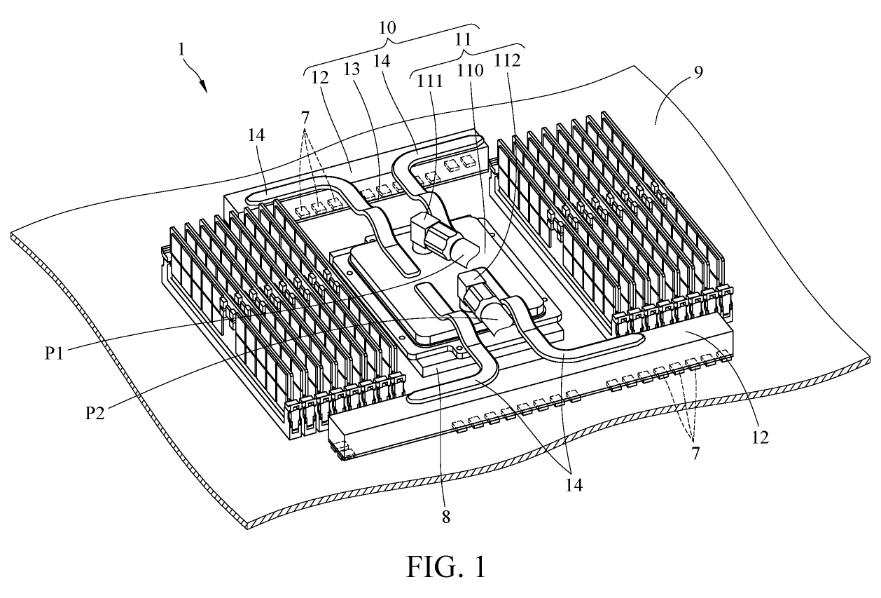

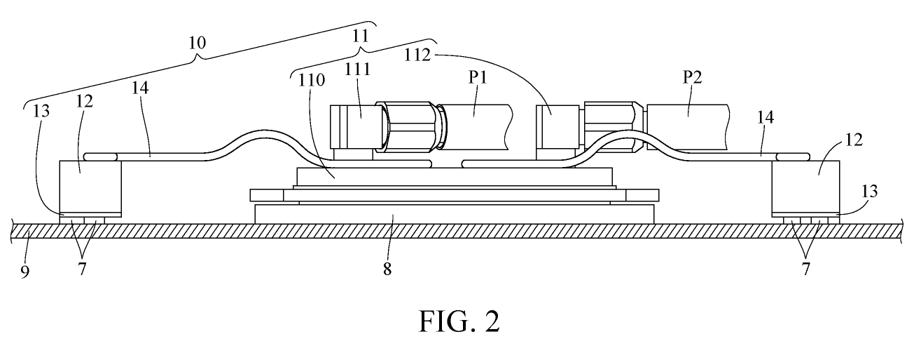

Referring to FIGS. 1 and 2, FIG. 1 is a partial perspective view of a server device according to one embodiment of the invention, and FIG. 2 is a side view of the server device as shown in FIG. 1.

In this embodiment, a server device 1 is provided. The server device 1 includes a motherboard 9, a central processing unit 8, a plurality of voltage regulators 7 and a liquid cooling heat dissipation assembly 10. The central processing unit 8 and the voltage regulators 7 are disposed on the motherboard 9. The liquid cooling heat dissipation assembly 10 is configured for cooling the central processing unit 8 and the voltage regulators 7.

The liquid cooling heat dissipation assembly 10 can include a cold plate 11, a plurality of thermally conductive metal components 12, a plurality of thermal pads 13 and a plurality of heat pipes 14.

The cold plate 11 is in thermal contact with the central processing unit 8 and is configured for coolant to flow through it. Specifically, for example, the cold plate 11 can include a plate body 110, an inlet fitting 111 and an outlet fitting 112. The plate body 110 is in thermal contact with the central processing unit 8, and the plate body 110 has a fluid chamber inside. The inlet fitting 111 and the outlet fitting 112 are disposed on the plate body 110, and both in fluid communication with the fluid chamber of the plate body 110. The inlet fitting 111 can be in fluid communication with a coolant distribution unit (not shown) via an inlet pipe P1, and the outlet fitting 112 can be in fluid communication with the coolant distribution unit via an outlet pipe P2. Therefore, a cooling loop is formed, enabling efficient heat dissipation for the central processing unit 8. The coolant distribution unit may, for example, include a heat exchanger configured for cooling the coolant. Moreover, the cold plate 11 may be made of copper, for instance, but the invention is not limited thereto.

The thermally conductive metal components 12 are in thermal contact with the voltage regulators 7. In addition, the thermally conductive metal components 12 are, for example, copper blocks, but the invention is not limited thereto. In this embodiment, the thermal pads 13 are respectively disposed between the thermally conductive metal components 12 and the voltage regulators 7, allowing the thermally conductive metal components 12 to be in thermal contact with the voltage regulators 7 via the thermal pad 13. However, the use of thermal pads is optional, and the invention is not limited thereto.

Two ends of the heat pipes 14 are respectively thermally coupled to the plate body 110 of the cold plate 11 and the thermally conductive metal components 12. Therefore, the heat generated by the voltage regulators 7 can be transferred to the cold plate 11 via the thermal pads 13, the thermally conductive metal components 12 and the heat pipes 14 through thermal conduction. Subsequently, the heat transferred to the cold plate 11 is carried away via the cooling loop formed by the cold plate 11 and the coolant distribution unit, thereby achieving efficient cooling of both the central processing unit 8 and the voltage regulators 7. Additionally, the heat pipes 14 may, for example, be high thermal conductivity heat pipes, but the invention is not limited thereto.

The invention is not limited to the quantity of thermally conductive metal components and heat pipes. In various configurations of the invention, the quantity of thermally conductive metal components and heat pipes can be adjusted to one or more based on actual design requirements.

According to the liquid cooling heat dissipation assembly and the server device as described in the above embodiment, through the design of the integrated liquid cooling heat dissipation assembly, effective cooling can be achieved for both the central processing unit and the voltage regulators. The cold plate is in thermal contact with the central processing unit, while the heat generated by the voltage regulators is transferred to the cold plate via the thermally conductive metal components and the heat pipes. Finally, the heat from both the central processing unit and the voltage regulators is carried away together by the coolant flowing through the cold plate, thereby achieving efficient cooling of both the central processing unit and voltage regulators via the liquid cooling heat dissipation assembly.

Furthermore, compared to conventional air-cooled servers, the liquid cooling heat dissipation assembly and the server device, as disclosed in the invention, adopt a liquid cooling solution, which offers thermal conductivity 15 to 25 times higher than that of air cooling, thereby enabling more efficient heat dissipation for higher heat flux densities, making it suitable for high-power central processing units and voltage regulators, and providing greater stability and a longer lifespan.

Moreover, compared to conventional air-cooled servers, the liquid cooling heat dissipation assembly and the server device, as disclosed in the invention, feature a more compact liquid cooling system design. Since cooling is achieved through liquid flow, it is not constrained by space limitations and offers superior heat dissipation performance.

Additionally, in conventional air-cooled servers, where only air cooling is used, the central processing unit and the voltage regulator are often thermal bottlenecks and frequently influence fan speed control, making them critical points for thermal management risks. The liquid cooling heat dissipation assembly and the server device, as disclosed in the invention, feature a liquid cooling design that effectively covers the major heat sources on the motherboard, significantly addressing this issue and thereby reducing the power consumption of system fans.

During the simulation testing of the liquid cooling heat dissipation assembly and the server device as described in the above embodiment, the coolant inlet temperature was set to 40°C, with a flow rate of 1.2 L/min, and a system simulation was conducted. In this test, the central processing unit (CPU) had a power consumption of 600W, while the voltage regulator (VR) had a power consumption of 98.142W. The simulation results showed that the maximum temperature of the CPU reached 67.7°C, which is below the specified limit of 72°C, and the temperature of the voltage regulator was 79.7°C, also below the specified limit of 90°C. These results confirm that the simulation meets the specification requirements of all components and provides sufficient thermal margin.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A liquid cooling heat dissipation assembly configured for cooling a central processing unit and at least one voltage regulator, and the liquid cooling heat dissipation assembly comprising:
a cold plate configured to be in thermal contact with the central processing unit and for a coolant to flow through;
at least one thermally conductive metal component configured to be in thermal contact with the at least one voltage regulator; and
at least one heat pipe, wherein two ends of the at least one heat pipe are respectively thermally coupled to the cold plate and the at least one thermally conductive metal component.

2. The liquid cooling heat dissipation assembly according to claim 1, wherein the at least one thermally conductive metal component is a copper block.

3. The liquid cooling heat dissipation assembly according to claim 1, further comprising at least one thermal pad disposed between the at least one thermally conductive metal component and the at least one voltage regulator.

4. The liquid cooling heat dissipation assembly according to claim 1, wherein the at least one voltage regulator comprises a plurality of voltage regulators, the at least one thermally conductive metal component comprises a plurality of thermally conductive metal components, and the at least one heat pipe comprises a plurality of heat pipes.

5. The liquid cooling heat dissipation assembly according to claim 1, wherein the cold plate comprises a plate body, an inlet fitting and an outlet fitting, the plate body is configured to be in thermal contact with the central processing unit and has a fluid chamber, the inlet fitting and the outlet fitting are disposed on the plate body and are in fluid communication with the fluid chamber, the inlet fitting is configured to be in fluid communication with a heat exchanger via an inlet pipe, and the outlet fitting is configured to be in fluid communication with the heat exchanger via an outlet pipe.

6. A server device comprising:
a motherboard;
a central processing unit disposed on the motherboard;
at least one voltage regulator disposed on the motherboard; and
a liquid cooling heat dissipation assembly comprising:
a cold plate in thermal contact with the central processing unit and configured for a coolant to flow through;
at least one thermally conductive metal component in thermal contact with the at least one voltage regulator; and
at least one heat pipe, wherein two ends of the at least one heat pipe are respectively thermally coupled to the cold plate and the at least one thermally conductive metal component.

7. The server device according to claim 6, wherein the at least one thermally conductive metal component is a copper block.

8. The server device according to claim 6, wherein the liquid cooling heat dissipation assembly further comprises at least one thermal pad disposed between the at least one thermally conductive metal component and the at least one voltage regulator.

9. The server device according to claim 6, wherein the at least one voltage regulator comprises a plurality of voltage regulators, the at least one thermally conductive metal component comprises a plurality of thermally conductive metal components, and the at least one heat pipe comprises a plurality of heat pipes.

10. The server device according to claim 6, wherein the cold plate comprises a plate body, an inlet fitting and an outlet fitting, the plate body is in thermal contact with the central processing unit and has a fluid chamber, the inlet fitting and the outlet fitting are disposed on the plate body and are in fluid communication with the fluid chamber, the inlet fitting is in fluid communication with a heat exchanger via an inlet pipe, and the outlet fitting is in fluid communication with the heat exchanger via an outlet pipe.
